(19) United States
(12) Patent Application Publication
(10) Pub. No.: US 2025/0022809 A1
(43) Pub. Date: Jan. 16, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wen-Jung TSAI, Taichung City (TW); Chih-Hsien CHIU, Taichung City (TW); Chien-Cheng LIN, Taichung City (TW); Shao-Tzu TANG, Taichung City (TW); Ko-Wei CHANG, Taichung City (TW)

(21) Appl. No.: 18/485,878

(22) Filed: Oct. 12, 2023

(30) Foreign Application Priority Data
Jul. 12, 2023 (TW) 112126034

(51) Int. Cl. H01L 23/552; H01L 21/304; H01L 23/00

(52) U.S. Cl. CPC H01L 23/552; H01L 21/3043; H01L 24/16; H01L 24/48; H01L 2224/16225; H01L 2224/48227; H01L 2924/3025

(57) ABSTRACT

An electronic package and a manufacturing method thereof are provided, in which an electronic element is disposed on a carrier structure, then a cladding layer is formed to cover the electronic element, and a shielding layer is formed on the cladding layer to cover the electronic element. The cladding layer is bonded to a shielding structure, and the shielding structure is located between the shielding layer and the electronic element, so as to prevent the electronic element from being subjected to external electromagnetic interference via multiple shielding mechanisms of the shielding structure and the shielding layer.

### BACKGROUND

### 1. Technical Field

The present disclosure relates to a semiconductor device, and more particularly, to an electronic package having a shielding structure and a manufacturing method thereof.

### 2. Description of Related Art

With the evolution of semiconductor technology, different packaging product types have developed in semiconductor products, and in order to improve electrical quality, many semiconductor products have the function of shielding to prevent electromagnetic interference (EMI).

As shown in FIG. 1, in a conventional semiconductor package 1, a semiconductor chip 11 is disposed on a package substrate 10, and the semiconductor chip 11 is electrically connected to the package substrate 10. Next, an encapsulant 13 is formed on the package substrate 10 to cover the semiconductor chip 11. Afterward, a shielding layer 12 is formed on the encapsulant 13 to protect the semiconductor chip 11 from external EMI.

However, in the conventional semiconductor package 1, if the external electromagnetic wave is too strong or the semiconductor chip 11 is a low-frequency element, and only a single metal layer is used as the shielding layer 12, it will be difficult to prevent electromagnetic interference from occurring, resulting in errors in the signal transmission of the semiconductor chip 11.

Therefore, how to overcome the above-mentioned drawbacks of the prior art has become an urgent issue to be solved at present.

### SUMMARY

In view of the various deficiencies of the prior art, the present disclosure provides an electronic package, which comprises: a carrier structure; an electronic element disposed on and electrically connected to the carrier structure; a cladding layer formed on the carrier structure and covering the electronic element; a shielding structure bonded to the cladding layer and covering the electronic element; and a shielding layer formed on the cladding layer, wherein the shielding structure is located between the shielding layer and the electronic element.

The present disclosure further provides a method of manufacturing an electronic package, the method comprises: disposing an electronic element on a carrier structure, wherein the electronic element is electrically connected to the carrier structure; forming a cladding layer on the carrier structure to cover the electronic element; bonding a shielding structure to the cladding layer to cover the electronic element; and forming a shielding layer on the cladding layer, wherein the shielding structure is located between the shielding layer and the electronic element.

In the aforementioned electronic package and method, the shielding structure includes a plurality of metal layers.

In the aforementioned electronic package and method, the shielding structure comprises a first metal layer, a second metal layer, a third metal layer, a fourth metal layer and a fifth metal layer, wherein a material forming the first metal layer is the same as a material forming the fifth metal layer, and a material forming the second metal layer is the same as a material forming the fourth metal layer.

In the aforementioned electronic package and method, the shielding structure includes a chromium layer, a nickel layer and/or a copper layer.

In the aforementioned electronic package and method, the shielding structure is a metal plate made of a single material.

In the aforementioned electronic package and method, the shielding structure is disposed outside the cladding layer.

In the aforementioned electronic package and method, the shielding structure is embedded in the cladding layer.

In the aforementioned electronic package and method, the present disclosure further comprises disposing a shielding member on the carrier structure, wherein the shielding member is covered by the cladding layer. For example, the shielding member is a metal block or a magnetically permeable block. Alternatively, a plurality of the shielding members are disposed on the carrier structure and surround the electronic element.

In the aforementioned electronic package and method, the present disclosure further comprises performing a pre-cut process, so that a cutting tool passes through the shielding structure and forms a cutting groove in the cladding layer. The present disclosure further comprises etching and removing metal burrs on a sidewall of the shielding structure. The present disclosure further comprises performing a singulation process corresponding to a position of the cutting groove, wherein the cutting tool passes through the cladding layer and the carrier structure, so that a stepped structure is formed on a side surface of the cladding layer.

As can be seen from the above, in the electronic package and the manufacturing method thereof of the present disclosure, the shielding structure is located between the shielding layer and the electronic element, so that external electromagnetic interference is reflected away from the electronic element via multiple shielding mechanisms, and external electromagnetic interference is even weakened by the buffering of these shielding mechanisms. Therefore, compared with the prior art, the electronic element of the electronic package of the present disclosure will not be subjected to electromagnetic interference, thereby effectively improving the reliability of the end product.

Furthermore, existing materials, processes and machines can be used in the manufacturing method of the present disclosure to manufacture the electronic package, so there is no need to increase or newly develop processes and materials, or even purchase machines. Therefore, the manufacturing method of the present disclosure can effectively save the production cost.

### BRIEF DESCRIPTION OF THE DRAWINGS

FIG. 1 is a schematic cross-sectional view of a conventional semiconductor package.

FIG. 2A, FIG. 2B-1, FIG. 2C and FIG. 2D are schematic cross-sectional views illustrating a manufacturing method of an electronic package according to a first embodiment of the present disclosure.

FIG. 2B-2 is a schematic partially enlarged cross-sectional view of FIG. 2B-1.

FIG. 3A-1, FIG. 3B, FIG. 3C and FIG. 3D are schematic cross-sectional views illustrating a manufacturing method of an electronic package according to a second embodiment of the present disclosure.

FIG. 3A-2 is a schematic cross-sectional view showing another aspect of FIG. 3A-1.

FIG. 4A is a schematic cross-sectional view showing another embodiment of FIG. 2A.

FIG. 4B-1 is a schematic cross-sectional view showing another aspect of FIG. 4A.

FIG. 4B-2 is a schematic top view of FIG. 4B-1.

FIG. 4C is a schematic cross-sectional view showing yet another embodiment of FIG. 2A.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

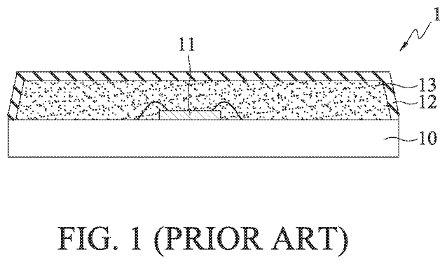

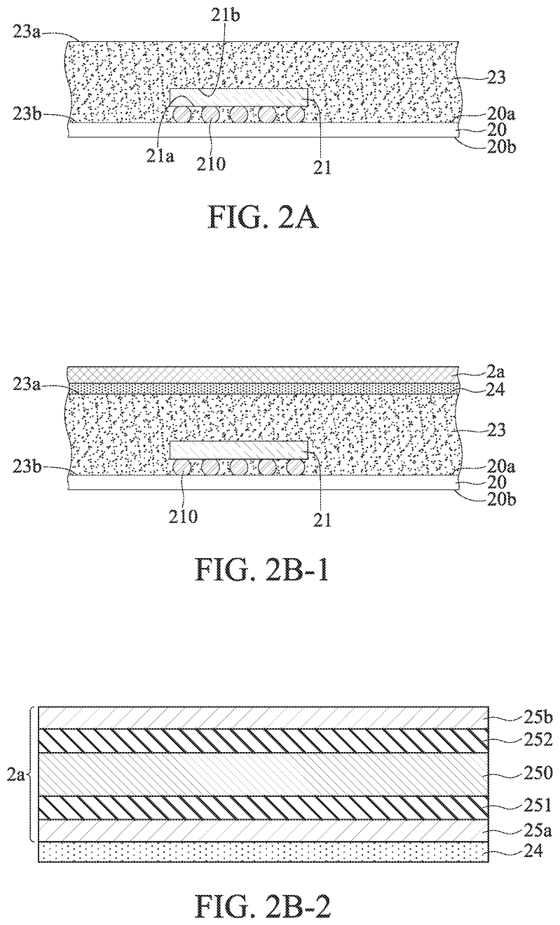

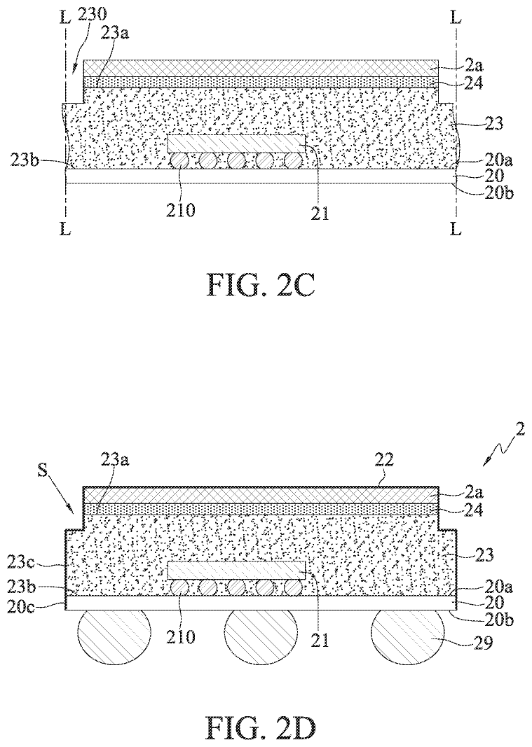

FIG. 2A, FIG. 2B-1, FIG. 2C and FIG. 2D are schematic cross-sectional views illustrating a manufacturing method of an electronic package 2 according to a first embodiment of the present disclosure.

As shown in FIG. 2A, a carrier structure 20 is provided and has a first side 20a and a second side 20b opposing the first side 20a, and at least one electronic element 21 is disposed on the first side 20a of the carrier structure 20. Next, a cladding layer 23 is formed on the first side 20a of the carrier structure 20, so that the electronic element 21 is covered by the cladding layer 23.

The carrier structure 20 is a circuit structure with a core layer (such as a hard substrate where a dielectric layer and a circuit layer formed on the dielectric layer are stacked on the core layer) or a circuit structure without a core layer (coreless) (such as a flexible substrate formed by stacking a dielectric layer and a circuit layer formed on the dielectric layer).

In an embodiment, the material for forming the circuit layer is copper, and the material for forming the dielectric layer is a dielectric material such as polybenzoxazole (PBO), polyimide (PI), prepreg (PP) and the like.

It should be understood that the carrier structure 20 can also be other types of carrier for carrying a chip, such as an organic board, a wafer, or other types of carrier board having metal routings, and the present disclosure is not limited to as such.

The electronic element 21 is an active element, a passive element, or a combination of the active element and the passive element, wherein the active element is such as a semiconductor chip, and the passive element is such as a resistor, a capacitor, or an inductor.

In an embodiment, the electronic element 21 is a radio-frequency chip, such as a Bluetooth chip or a Wi-Fi chip, but the electronic element 21 can also be other types of electronic element not subject to electromagnetic interference. For example, the electronic element 21 has an active surface 21a and an inactive surface 21b opposing the active surface 21a, and a plurality of electrode pads (not shown) are formed on the active surface 21a, so that these electrode pads are disposed on the first side 20a of the carrier structure 20 in a flip-chip manner via a plurality of conductive bumps 210 made of solder material to electrically connect the circuit layer; alternatively, the electronic element 21 can be electrically connected to the circuit layer via a plurality of bonding wires (not shown) in a wire-bonding manner. However, the manner in which the electronic element 21 is electrically connected to the circuit layer is not limited to the above.

The cladding layer 23 has a first surface 23a and a second surface 23b opposing the first surface 23a, and the cladding layer 23 is bonded onto the first side 20a of the carrier structure 20 via the second surface 23b thereof.

In an embodiment, the cladding layer 23 is made of an insulating material, such as polyimide (PI), dry film, encapsulant such as epoxy resin, or molding compound. For example, the manufacturing process of forming the cladding layer 23 on the carrier structure 20 can be selected from various manners such as liquid compound, injection, lamination, or compression molding.

As shown in FIG. 2B-1, a shielding structure 2a is formed on the first surface 23a of the cladding layer 23.

In an embodiment, the shielding structure 2a includes a plurality of metal layers, as shown in FIG. 2B-2. For example, a first metal layer 25a made of such as a chromium material, a second metal layer 251 made of such as a nickel material, a third metal layer 250 made of such as a copper material, a fourth metal layer 252 made of such as a nickel material and a fifth metal layer 25b made of such as a chromium material are stacked in order away from the electronic element 21. The material for forming the first metal layer 25a is the same as the material for forming the fifth metal layer 25b, and the material for forming the second metal layer 251 is the same as the material for forming the fourth metal layer 252.

Moreover, an insulating layer 24 may be formed on the first surface 23a of the cladding layer 23 first, so that the insulating layer 24 is in contact with the first surface 23a of the cladding layer 23 and the first metal layer 25a of the shielding structure 2a. The insulating layer 24 is made of, for example, a solder-resist material.

As shown in FIG. 2C, a pre-cut (half-cut) process is performed to form a cutting groove 230 on the first surface 23a of the cladding layer 23. In this pre-cut process, a cutting tool will pass through the metal portion of the shielding structure 2a, so that metal burrs will be generated, and then the sidewall of the shielding structure 2a can be etched with an etching solution to cut the extended metal burrs.

In an embodiment, a half-cut form is used in the pre-cut process, so that the cutting groove 230 does not penetrate through the carrier structure 20 and the cladding layer 23.

As shown in FIG. 2D, corresponding to the position of the aforementioned cutting groove 230, a singulation process is performed along a cutting path L shown in FIG. 2C, so that the cladding layer 23 and the carrier structure 20 are respectively formed with side surfaces 23c, 20c. Since this full cutting process only cuts non-metallic parts (that is, the cutting tool only passes through the cladding layer 23 and the carrier structure 20), the problem of metal burrs will not occur. Next, a shielding layer 22 is formed on the shielding structure 2a and the insulating layer 24, and the shielding layer 22 is extended onto the side surface 23c of the cladding layer 23 and the side surface 20c of the carrier structure 20, so that the electronic package 2 is achieved, wherein the shielding structure 2a is located between the shielding layer 22 and the electronic element 21.

In an embodiment, through the aforementioned half-cut process and full-cut process, the side surface 23c of the cladding layer 23 is formed with a stepped structure S (e.g., a step-shaped structure) via the cutting groove 230.

Moreover, the shielding layer 22 is formed of materials such as gold (Au), silver (Ag), copper (Cu), nickel (Ni), iron (Fe), aluminum (Al), stainless steel (steel use stainless [SUS]) and the like. For example, the shielding layer 22 can be formed by electroplating, coating, sputtering, chemical plating, electroless plating, or vapor deposition. Alternatively, the shielding layer 22 can also be made of a metal cover plate or a conductive film, and then arranged in a sticking manner.

Also, before performing the singulation process, a plurality of conductive elements 29 such as solder balls can be formed on the second side 20b of the carrier structure 20 according to requirements, and the plurality of conductive elements 29 are electrically connected to the circuit layer of the carrier structure 20 and are used for subsequent connection of electronic devices such as package structures, chips, or circuit boards (not shown).

Therefore, in the manufacturing method of the present disclosure, the shielding structure 2a is formed between the shielding layer 22 and the electronic element 21, so that external electromagnetic interference is reflected away from the electronic element 21 via multiple shielding mechanisms, and external electromagnetic interference is even weakened by the buffering of these shielding mechanisms. Hence, compared with the prior art, the electromagnetic shielding effect of the upper area of the electronic element 21 is strengthened in the electronic package 2 of the present disclosure, so that the electronic element 21 will not be subjected to electromagnetic interference, thereby improving the reliability of the end product.

Furthermore, existing materials, processes and machines can be used in the manufacturing method of the present disclosure to manufacture the electronic package 2, so there is no need to increase or newly develop processes and materials, or even purchase machines. Therefore, the manufacturing method of the present disclosure can effectively save the production cost.

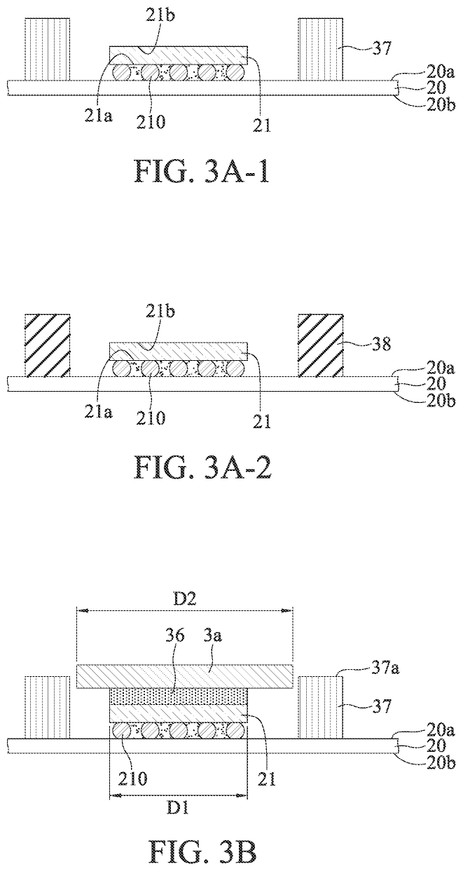

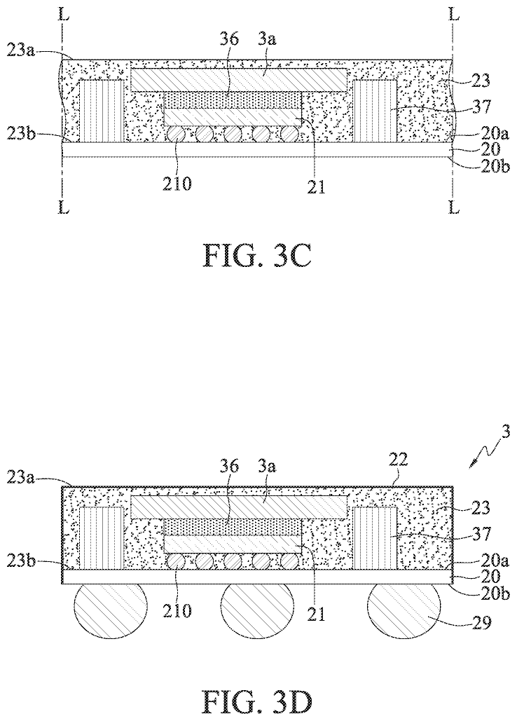

FIG. 3A-1, FIG. 3B, FIG. 3C and FIG. 3D are schematic cross-sectional views illustrating a manufacturing method of an electronic package 3 according to a second embodiment of the present disclosure. The difference between the second embodiment and the first embodiment lies in the position of a shielding structure 3a, and other manufacturing processes are substantially the same, so the similarities will not be repeated below.

As shown in FIG. 3A-1, a carrier structure 20 is provided and has a first side 20a and a second side 20b opposing the first side 20a, and at least one electronic element 21 is disposed on the first side 20a of the carrier structure 20. Next, at least one shielding member 37 is disposed on the first side 20a of the carrier structure 20.

In an embodiment, the shielding member 37 includes a magnetically permeable material (e.g., a magnetically conductive material), such as a ferrite block or an inductor block. In other embodiments, as shown in FIG. 3A-2, a shielding member 38 can also be a metal block such as a copper pillar.

As shown in FIG. 3B, following the process shown in FIG. 3A-1, the shielding structure 3a is formed on the inactive surface 21b of the electronic element 21.

In an embodiment, the shielding structure 3a is a metal plate made of a single material such as a copper sheet, and the shielding structure 3a is disposed on the inactive surface 21b of the electronic element 21 via a bonding layer 36. For example, the bonding layer 36 is made of an adhesive material such as epoxy resin.

Moreover, a width D2 of the shielding structure 3a is greater than a width D1 of the electronic element 21. For example, the position of the shielding structure 3a relative to the first side 20a of the carrier structure 20 is higher than the position of a top surface 37a of the shielding member 37 relative to the first side 20a of the carrier structure 20.

As shown in FIG. 3C, a cladding layer 23 is formed on the first side 20a of the carrier structure 20, so that the electronic element 21, the bonding layer 36, the shielding member 37 and the shielding structure 3a are covered by the cladding layer 23.

In an embodiment, neither the shielding member 37 nor the shielding structure 3a is exposed from the cladding layer 23.

As shown in FIG. 3D, the singulation process is performed along the cutting path L shown in FIG. 3C. Next, a shielding layer 22 is formed on the cladding layer 23 and extended onto the side surface 20c of the carrier structure 20, so that the electronic package 3 is achieved, wherein the shielding structure 3a is located between the shielding layer 22 and the electronic element 21.

In an embodiment, before performing the singulation process, a plurality of conductive elements 29 such as solder balls can be formed on the second side 20b of the carrier structure 20 according to requirements, and the plurality of conductive elements 29 are electrically connected to the circuit layer of the carrier structure 20 and are used for subsequent connection of electronic devices such as package structures, chips, or circuit boards (not shown).

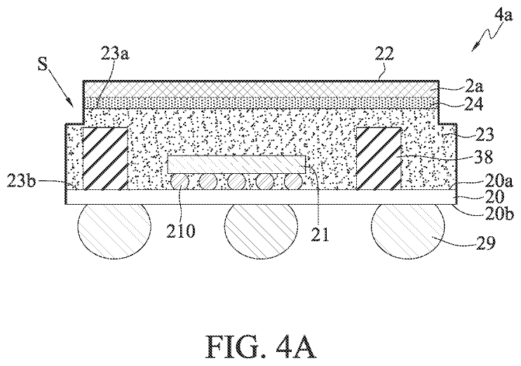

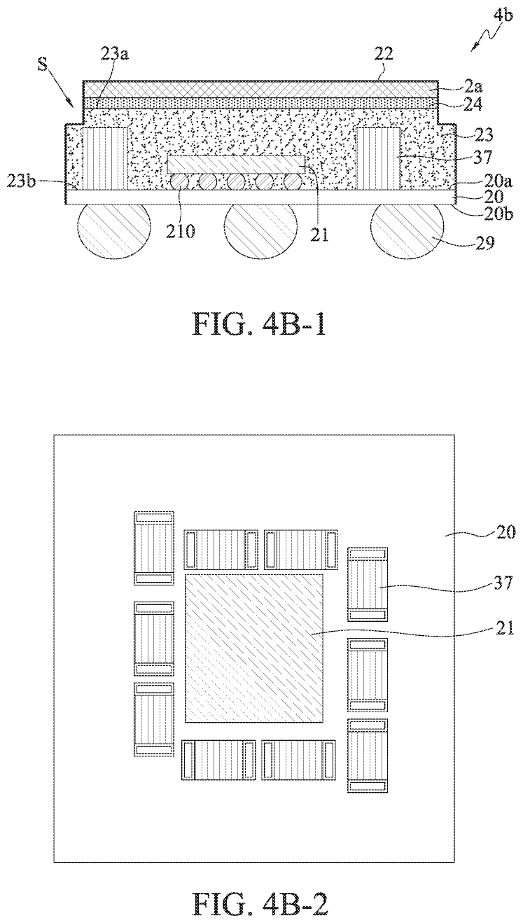

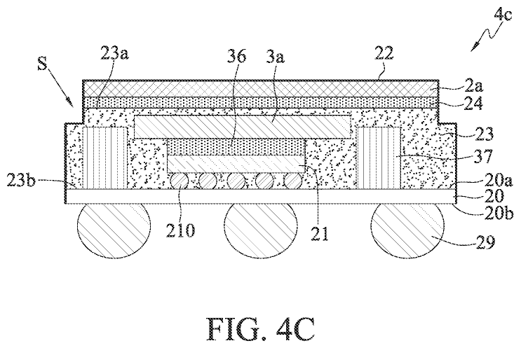

Furthermore, for an electronic package 4a shown in FIG. 4A or an electronic package 4b shown in FIG. 4B-1, the shielding member 37, 38 can also be configured on the first side 20a of the carrier structure 20 of the first embodiment. For example, the electronic element 21 can be surrounded by a plurality of the shielding members 37, as shown in FIG. 4B-2.

Moreover, for an electronic package 4c shown in FIG. 4C, the shielding structure 3a can also be disposed on the inactive surface 21b of the electronic element 21 of the first embodiment via the bonding layer 36.

Therefore, in the manufacturing method of the present disclosure, the shielding layer 22, the shielding structure 2a, 3a and the shielding member 37, 38 are configured around the electronic element 21, so that when the electronic package 2, 3, 4a, 4b, 4c is in operation, the electronic element 21 will not suffer from external electromagnetic interference (EMI), especially the side surface of the electronic element 21 can be prevented from being subjected to electromagnetic interference. Hence, compared with the electronic package 2 of the first embodiment, the electronic package 3, 4a, 4b, 4c of the second embodiment has better electrical operation functions, thereby improving the electrical performance of end products.

Furthermore, existing materials, processes and machines can be used in the manufacturing method of the present disclosure to manufacture the electronic package 3, 4a, 4b, 4c, so there is no need to increase or newly develop processes and materials, or even purchase machines. Therefore, the manufacturing method of the present disclosure can effectively save the production cost.

The present disclosure also provides an electronic package 2, 3, 4a, 4b, 4c, which comprises: a carrier structure 20, at least one electronic element 21, a cladding layer 23, a shielding layer 22 and a shielding structure 2a, 3a.

The electronic element 21 is disposed on the carrier structure 20 and electrically connected to the carrier structure 20.

The cladding layer 23 is formed on the carrier structure 20 and covers the electronic element 21.

The shielding structure 2a, 3a is bonded to the cladding layer 23 to cover the electronic element 21.

The shielding layer 22 is formed on the cladding layer 23, and the shielding structure 2a, 3a is positioned between the shielding layer 22 and the electronic element 21.

In one embodiment, the shielding structure 2a includes a plurality of metal layers.

In one embodiment, the shielding structure 2a comprises a first metal layer 25a, a second metal layer 251, a third metal layer 250, a fourth metal layer 252 and a fifth metal layer 25b, wherein a material forming the first metal layer 25a is the same as a material forming the fifth metal layer 25b, and a material forming the second metal layer 251 is the same as a material forming the fourth metal layer 252.

In one embodiment, the shielding structure 2a includes a chromium layer, a nickel layer and/or a copper layer.

In one embodiment, the shielding structure 3a is a metal plate made of a single material.

In one embodiment, the shielding structure 2a is disposed outside the cladding layer 23.

In one embodiment, the shielding structure 3a is embedded in the cladding layer 23.

In one embodiment, in the electronic package 3, 4a, 4b, 4c, a shielding member 37, 38 is disposed on the carrier structure 20, so that the shielding member 37, 38 is covered by the cladding layer 23. For example, the shielding member 37, 38 is a metal block or a magnetically permeable block (e.g., a magnetically conductive block). Alternatively, a plurality of the shielding members 37 surrounding the electronic element 21 are disposed on the carrier structure 20.

To sum up, in the electronic package and the manufacturing method thereof of the present disclosure, the shielding structure is located between the shielding layer and the electronic element, so that external electromagnetic interference is reflected away from the electronic element via multiple shielding mechanisms, and external electromagnetic interference is even weakened by the buffering of these shielding mechanisms. Therefore, the electronic element of the electronic package of the present disclosure will not be subjected to electromagnetic interference, thereby effectively improving the reliability of the end product.

Furthermore, existing materials, processes and machines can be used in the manufacturing method of the present disclosure to manufacture the electronic package, so there is no need to increase or newly develop processes and materials, or even purchase machines. Therefore, the manufacturing method of the present disclosure can effectively save the production cost.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure;
an electronic element disposed on and electrically connected to the carrier structure;
a cladding layer formed on the carrier structure and covering the electronic element;
a shielding structure bonded to the cladding layer and covering the electronic element; and
a shielding layer formed on the cladding layer, wherein the shielding structure is located between the shielding layer and the electronic element.

2. The electronic package of claim 1, wherein the shielding structure includes a plurality of metal layers.

3. The electronic package of claim 1, wherein the shielding structure comprises a first metal layer, a second metal layer, a third metal layer, a fourth metal layer and a fifth metal layer, wherein a material forming the first metal layer is the same as a material forming the fifth metal layer, and a material forming the second metal layer is the same as a material forming the fourth metal layer.

4. The electronic package of claim 1, wherein the shielding structure includes a chromium layer, a nickel layer and/or a copper layer.

5. The electronic package of claim 1, wherein the shielding structure is a metal plate made of a single material.

6. The electronic package of claim 1, wherein the shielding structure is disposed outside the cladding layer.

7. The electronic package of claim 1, wherein the shielding structure is embedded in the cladding layer.

8. The electronic package of claim 1, further comprising a shielding member disposed on the carrier structure, wherein the shielding member is covered by the cladding layer.

9. The electronic package of claim 8, wherein the shielding member is a metal block or a magnetically permeable block.

10. The electronic package of claim 8, wherein a plurality of the shielding members are disposed on the carrier structure and surround the electronic element.

11. The electronic package of claim 1, wherein a stepped structure is formed on a side surface of the cladding layer.

12. A method of manufacturing an electronic package, comprising:
disposing an electronic element on a carrier structure, wherein the electronic element is electrically connected to the carrier structure;
forming a cladding layer on the carrier structure to cover the electronic element;
bonding a shielding structure to the cladding layer to cover the electronic element; and
forming a shielding layer on the cladding layer, wherein the shielding structure is located between the shielding layer and the electronic element.

13. The method of claim 12, wherein the shielding structure includes a plurality of metal layers.

14. The method of claim 12, wherein the shielding structure comprises a first metal layer, a second metal layer, a third metal layer, a fourth metal layer and a fifth metal layer, wherein a material forming the first metal layer is the same as a material forming the fifth metal layer, and a material forming the second metal layer is the same as a material forming the fourth metal layer.

15. The method of claim 12, wherein the shielding structure includes a chromium layer, a nickel layer and/or a copper layer.

16. The method of claim 12, wherein the shielding structure is a metal plate made of a single material.

17. The method of claim 12, wherein the shielding structure is disposed outside the cladding layer.

18. The method of claim 12, wherein the shielding structure is embedded in the cladding layer.

19. The method of claim 12, further comprising disposing a shielding member on the carrier structure, wherein the shielding member is covered by the cladding layer.

20. The method of claim 19, wherein the shielding member is a metal block or a magnetically permeable block.

21. The method of claim 19, wherein a plurality of the shielding members are disposed on the carrier structure and surround the electronic element.

22. The method of claim 12, further comprising performing a pre-cut process, so that a cutting tool passes through the shielding structure and forms a cutting groove in the cladding layer.

23. The method of claim 22, further comprising etching and removing metal burrs on a sidewall of the shielding structure.

24. The method of claim 22, further comprising performing a singulation process corresponding to a position of the cutting groove, wherein the cutting tool passes through the cladding layer and the carrier structure, so that a stepped structure is formed on a side surface of the cladding layer.
